(19) United States
(12) Patent Application Publication
(10) Pub. No.: US 2009/0061544 A1
(43) Pub. Date: Mar. 5, 2009

(54) TRAJECTORY BASED CONTROL OF PLASMA PROCESSING

(75) Inventors: JOHN P. HOLLAND, San Jose, CA (US); John M. Yamartino, Ossining, NY (US); Thorsen B. Lill, Santa Clara, CA (US); Meihua Shen, Fremont, CA (US); Alexander Paterson, San Jose, CA (US); Valentin N. Todorow, Palo Alto, CA (US)

Correspondence Address: LAW OFFICES OF CHARLES GUENZER;ATTN: APPLIED MATERIALS, INC., 2211 PARK BOULEVARD, P.O. BOX 60729, PALO ALTO, CA, 94306, US

(73) Assignee: Applied Materials, Inc., Santa Clara, CA (US)

(21) Appl. No.: 11/948,030

(22) Filed: Nov. 30, 2007

Related U.S. Application Data
(60) Provisional application No. 60/969,093, filed on Aug. 30, 2007.

(51) Int. Cl. H01L 21/66; H01L 21/306

(52) U.S. Cl. 438/14; 156/345.24; 257/E21.528

(57) ABSTRACT

A method of controlling a plasma processing according to trajectories connecting start and stop values of parameters controlling the plasma processing, for example, gas flow and power supplied to generate the plasma. The trajectories maybe based on equations including at least time as a variable. At set times within the processing, the values of the parameters are updated according to the predetermined trajectories. Sensors associated with the chamber may also adjust the trajectories, provide variables to the equations, and/or define the trajectories.

### RELATED APPLICATIONS

This application claims benefit of provisional application 60/969,093 filed Aug. 30, 2007.

### FIELD OF THE INVENTION

Embodiments of the invention relate generally to plasma processing of semiconductor substrates, such as plasma etch. In particular, embodiments of the invention relate to the control algorithm for regulating and terminating the plasma process.

### BACKGROUND ART

Plasma etching is one of several plasma processing steps used to deposit, condition, etch, and otherwise process a semiconductor substrate, usually a silicon wafer. Electrical means excite a processing gas into a plasma and the highly reactive plasma gas acts upon the substrate. The process may include deposition, such as plasma enhanced chemical deposition (PECVD) or plasma sputtering from a target, conditioning of an already deposited layer to chemically change an already deposited material, or etching to remove a deposited material, usually in a patterned etch to selectively expose an underlying layer.

An example of plasma etching is opening a gate contact in the structure illustrated in the cross-sectional view of FIG. 1. A silicon substrate 10, which may include doped regions near its surface, is overlaid with a thin gate oxide layer 12, most typically formed of silicon dioxide although high-k dielectrics can also be used. A gate contact structure 14 is deposited and defined. For example, the gate contact structure 14 may include an oxide-nitride-oxide tri-layer for a non-volatile memory. A polysilicon layer 16 is then deposited over exposed portion of the oxide layer 12 and over the gate contact structure 14 and maybe incorporated into the gate contract structure 14. A mask layer 18 is deposited and photographically patterned to leave a mask over an area of the polysilicon layer 16 to remain over the gate contact structure 14 to provide a contact to the gate formed by the combination of the gate contact structure 14 and the gate oxide layer 12 over the underlying silicon layer 10. The mask layer 18 also masks areas away from the MOS transistor being formed. Source and drains will be formed in the silicon substrate 10 around the gate after the formation of the polysilicon contact.

The patterned mask layer 18 is used as a mask for a plasma etch of the polysilicon layer 16. It may consist of not only photoresist but also hard mask layers more resistant to polysilicon etching chemistry. The figure shows the structure midway through etching process including partially developing source and drain contact holes 20, 22 as well as a developing gate contact 24. Ideally, the etching proceeds until the non-masked regions of the polysilicon layer 16 are etched away and expose the underlying gate oxide layer 12. The exposed areas in the source and drain contact holes 20, 22 are then processed to form the source and drain of the MOS transistor and their contacts, which are isolated from the gate contact 24.

The etching maybe performed in a plasma etch reactor 30 schematically illustrated in the cross-sectional view of FIG. 2. Such a reactor is available from Applied Materials, Inc. of Santa Clara, Calif. as the DPS II plasma etcher. The plasma etch reactor 30 includes a main vacuum chamber 32 which is generally arranged around a central axis 34 and which is electrically grounded although unillustrated chamber shields may provide the required grounding. A vacuum pump system includes a vacuum pump 38 connected to the main vacuum chamber 32 through a throttle valve 40 to pump the chamber 32 to a vacuum in the low Torr range. A pedestal 42 supports a wafer 44 to be etched. A resistive heater 46 selectively driven by a power supply 48 increases the temperature of the pedestal and maintains it at a desired temperature. Alternately or additionally, an unillustrated chiller may supply chilling fluid to the pedestal to 42 to selectively cool it to a desired temperature. A helium gas source 50 supplies helium through a mass flow controller 52 as a thermal transfer gas to a thin gas chamber 54 between the wafer 44 and the pedestal 42 to thermally couple the two on a time scale much quicker than the time required to heat or cool the pedestal 42. An electrostatic chuck 56 embedded at the surface of the pedestal 42 is selectively powered from a chuck power supply 58 to chuck the wafer 44 to the pedestal 42.

A dielectric dome 60 is vacuum sealed to the main vacuum chamber 32 and a helical RF coil 62 wrapped around the dome 60 is powered by a source RF power supply 64 to couple energy into the reactor 30 to excite and maintain a plasma of the processing gas. A match circuit 66 is interposed between the source RF power supply 64 and the RF coil 62 to automatically match the impedance of the two as the plasma is ignited and its conditions thereafter varied. The match circuit 66 may also be externally controlled to control the amount of RF power supplied into the reactor 30. Multiple gas source 70, 72 supply different processing gases into the reactor 30 through respective mass flow controllers 74, 76 connected to usually multiple gas jets 78 arranged around the periphery of a processing space 80 between the dome 60 and the wafer 44. The RF coil 62 excites the processing gases into a plasma in the processing space 80 to etch and otherwise process the wafer 44.

A bias RF power supply 80 connected through the pedestal 42 through a capacitive coupling circuit 82 may be used to accelerate ions in the plasma of the processing gas and attract them to the wafer 44. An optical emission spectrometer (OES) 84 views the processing space 80 above the wafer 44 to monitor the optical emission from the plasma to detect emissions characteristic of etching products, particularly of the layer underlying the one to be etched to enable end-point detection of the etching process. A computerized controller 90 controls the operation of the reactor 30 according to a recipe recorded on a recordable medium 92 and read by the controller 90. The recipes are timed according to a clock 92 connected to the controller 90. The controller 90 receives inputs from the recordable medium 92, the clock 94, and the optical emission spectrometer 84 among other inputs and controls the throttle valve 40, the power supplies 48, 58, 64, 80, the match circuit 66, the mass flow controllers 52, 74, 76 and other unillustrated control functions.

The etching process of forming the contact structure of FIG. 1 and most other etched structures is typically not straightforward. The plasma needs to be ignited. A breakthrough etch step removes the native oxide layer form on top of the polysilicon layer 16. A main etch step defines most of the portion of the gate feature before the thin gate oxide layer 12 is reach. During the main etch step, selectivity to the under layer is not a principal concern but a good etch profiles as well as selectivity to the mask layer 18 are needed. The main process of etching through the polysilicon layer 16 maybe divided into multiple sub-steps to account for the increasing depth of etching into the relatively narrow source and drain contact holes 20, 22 as well as for some initial processing. During a soft landing step during which the gate oxide layer should be exposed, selectivity to the underlying oxide is important but a good etch profile needs to be maintained. Process conditions, also, vary somewhat over different areas of the wafer and over time so that etch rates vary. As a result, the etching chemistry and etching conditions are carefully chosen in the last stages of etching, called over etch, so that the etching selectively removes the polysilicon layer 16 over the gate oxide layer 12. The main etch step can be timed to stop approximately at the gate oxide layer 12. However, timing alone is not sufficient. The thickness of the polysilicon layer 14 may vary somewhat, both between different areas of the wafer and between different wafers, so that required etch depths vary. Therefore, the process conditions change between main etch and over etch. Furthermore, the over etch may be divided into two separate steps with the final step assuring the removal of the last of the polysilicon. The over etch step requires a high selectivity to oxide to clear the remaining polysilicon residues from everywhere and to define the bottom corner of the profile. Etch anisotropy and etch rate can be sacrificed in the over etch. In traditional plasma processing, the set points of the process parameters are fixed within discrete recipe steps of varying lengths.

The transition between the multiple steps of the plasma etching process are typically controlled according to a recipe or a predetermined process sequence and parameters in the recordable medium 92 of FIG. 2. In this process, each step is accorded so many seconds according to the clock 94 before the conditions are transitioned to the next step.

The number of steps in a typical etching recipe may be somewhat large, perhaps six or eight, in view of the need to etch different portions of the narrow hole and to somewhat over etch to assure complete etching through the polysilicon through without seriously etching into the underlying layer. Typically, each step is assigned a predetermined set of control parameters to effect for a set period of time. These periods are typically stated in increments of one second. The main exception is the end point condition monitored through the optical emission spectrometer 84 or other means in which the last step is terminated once it is detected that the last layer has been etched through.

Nonetheless, time-controlled multi-step etching with static set points and other desired processes or recipes of the prior art may be considered to be too constraining in view of the narrow process window and continuously evolving etching environment. Particularly, in etching deep and narrow features, for example, in etching polysilicon to form a gate over the oxide gate, the highly selective etching chemistry is balanced to operate near the critical edge between etch and deposition. Further, as the etch front proceeds deeper into the hole, the gas composition at the etching front is changing and etch by-products become important. If the etch process is not carefully controlled, etch stop may occur in which the etch rate falls to zero and the hole is never completely etched to its desired bottom.

### SUMMARY

According to one aspect of the invention, a method of etching is provided. The method includes controlling processing parameters of a plasma processing system, such as an etch reactor, over at least a phase of the process according to predefined trajectories connecting start and stop values of the parameters. At set times within a period, the trajectories are used to update the parameters. The set times, typically ten or more, are preferably separated by a fixed time increment.

In one exemplary embodiment, the method includes setting start and stop values for a plurality of control functions extending over a time period, defining trajectories of the control functions connecting the start and stop values over the time period, and at each of a plurality of time points within the time period separated by a time increment, determining values of the control functions according to the trajectories.

In another exemplary embodiment, a system for processing a substrate is provided. The system includes a plasma processing chamber for processing the substrate. The system further includes at least one power supply operatively associated with a plasma within the chamber, at lesat one gas supply supplying a gas for the plasma, and a control system operatively coupled to the chamber. The control system controls the plurality of parameter functions according to respective trajectories extending over a time period between respective start values and stop values and being controlled at a plurality of temperature points within the time period separated by a fixed time increment. A plurality of parameter functions is also provided for controlling the processing.

In one embodiment, sensors associated with the processing may be used to update or partially control the trajectories to thereby affect the intermediate parameter values.

In one embodiment, trajectories connecting start and stop values maybe defined by equations having at least time as a variable. Sensor outputs may be used as additional variables in the equation.

In one embodiment, a clock may be used to trigger the parameter update at fixed intervals.

In one embodiment, multiple sequential trajectories may define an entire process. Preferably, the sequential trajectories are smoothly joined.

### BRIEF DESCRIPTION OF THE DRAWINGS

FIG. 1 is a cross-sectional view of a polysilicon gate being etched into a polysilicon layer.

FIG. 2 is a schematic cross-sectional view of a plasma reactor in which the invention may be practiced including performing the polysilicon gate etch of FIG. 1.

FIG. 3 is a flow diagram of one embodiment of a control process of the invention.

FIG. 4 is a graph showing several trajectories for one embodiment of an initial phase of a polysilicon gate etch.

FIG. 5 is a graph showing several trajectories for one embodiment of the main etch of the polysilicon gate etch.

FIG. 6 is a flow diagram of another embodiment of the control process of the invention including dynamic readjustment of the trajectories.

### DETAILED DESCRIPTION OF THE PREFERRED EMBODIMENTS

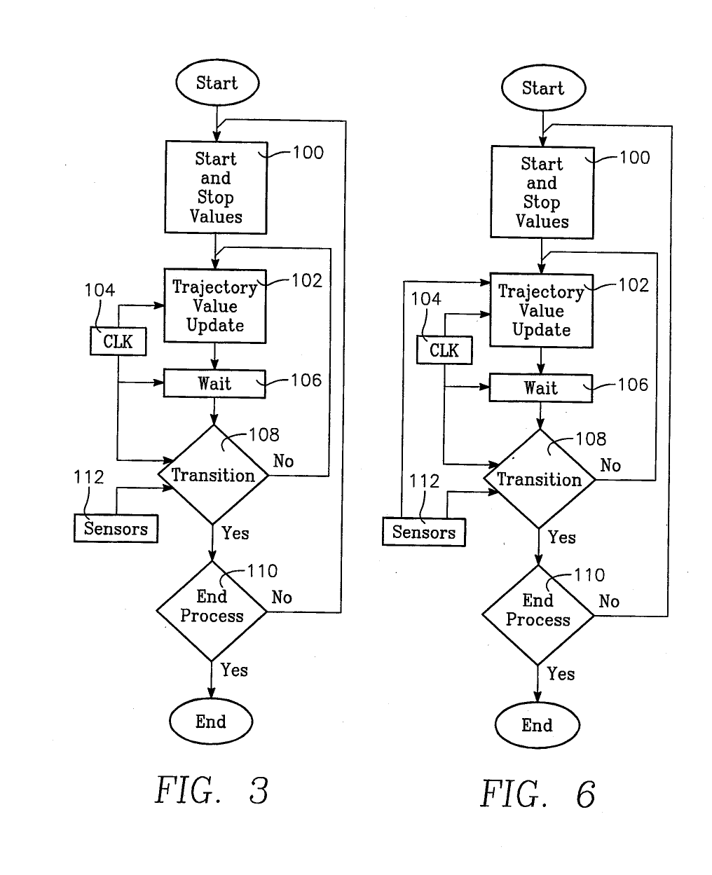

Embodiments of the present invention include a nearly continuous adjustment of process parameters rather than set levels of predetermined duration. A flow chart in FIG. 3 functionally illustrates an embodiment of the invention. At the start of processing a wafer, a set of start and stop values are provided at an initial values step 100. In one embodiment, a first phase of the process is selected for all controlled parameters such as chamber pressure, power levels, gas flows and the like. In one embodiment, the start and stop values represent the values of the controlled parameters at the beginning and end of the processing phase. The values are updated according to predetermined trajectories for each of the controlled parameters at an update step 102. In one embodiment, the start and stop values and the trajectories are stored in a controller memory as the recipe for the wafer process being practiced. The updating depends upon the elapsed time since the beginning of the phase of the process as determined by a clock 104. Each trajectory smoothly connects the start and stop values. It may be based upon a mathematical algorithm or equation having the start and stop values as its end points. A simplest algorithm is a linear interpolation between the end points. Some trajectories may be flat, such as an electrostatic chuck voltage once plasma processing has started. Others may represent uniform zero values, such as an RF coil not being powered in one phase of the processing. More complex trajectories may include regions of differing slope connecting the end points or intermediate peaks and valleys between the end points. For a limited number of updating periods in a phase, the trajectory may be represented by a table of intermediate values. However, the discrete representation of the trajectory typically uses a larger number of time periods and the time period are typically of a single small duration, unlike the generally small number of time periods of variable and longer duration in the prior art control algorithm.

After the values are updated at the update step 102, a waiting period is provided at a wait step 106 during which the wafer is being processed or other chamber functions are being performed according to the updated values set in update step 102. The waiting period in the wait step 106 is exited when a wait period is exceeded as compared to the clock 104. In one embodiment, the waiting period at the wait step 106, which determines the update period, is relatively short compared to usual processing times, typically less than 100 milliseconds.

After the waiting period in the wait step 106, a transition test 108 determines if the current phase of processing has been completed. In a regular termination of the processing phase, the clock 104 is consulted to determine if the intended length of the phase has been reached and the parameter values have reached their stop values. If the transition test 108 determines that the current processing phase has not ended, the controller returns the process to the update step 102 to update the parameter control values according to the already selected trajectories.

If the transition test 108 determines that a transition to a new processing phase should be made, the old process ends in an end test 110. In one embodiment, the end test 110 determines if all the process phases have been completed or if other process phases remain. If process phases remain, execution returns to the end values step 100 to select start and stop values for the next phase. If no process phases remain, processing of the current wafer is ended. It is noted that the final process in plasma processing a wafer includes shutting off the power supplies and gas flow, dechucking the wafer, and preparing the chamber for wafer transfer.

The update period may be made short enough such that process interrupts, such as the breakthrough signal from the OES sensor 84 or a signal indicating successful plasma ignition, can be handled by interrogating all relevant sensors 112 during the transition test 108 or other time. If any sensor 112 indicates that the current processing phase should be terminated, an abnormal transition is made prior to end of the intended processing phase length and prior to attainment of the stop values and the stop time associated with them.

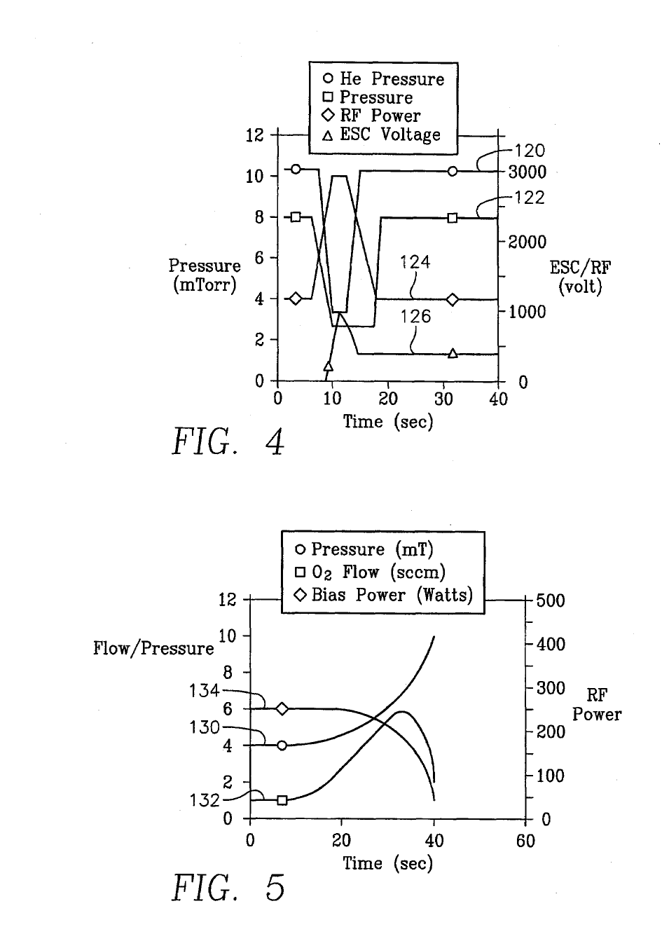

A first example of a processing phase includes the plasma ignition of a low pressure process and the subsequent process for breakthrough of the native oxide overlying a polysilicon layer to be etched later in the process. The graph of FIG. 4 illustrates the trajectories for four process parameters in this initial phase according to one recipe. Plot 120 shows the trajectory for the supply of helium backside cooling gas. Plot 122 shows the trajectory for the chamber pressure. Plot 124 shows the RF power applied to the RF coil. Plot 126 shows the voltage applied to the electrostatic chuck. To successfully initiate a low-pressure plasma process using an RF source, the RF power needs to be applied to the source coil when the gas pressure in the chamber is high enough to achieve plasma ignition. Concurrently, the voltage on the electrostatic chuck needs to be low enough to minimize loss of the plasma prior to the RF matching circuit achieving full coupling of the RF source power into the plasma. Immediately following the successful plasma strike, the pressure, gas flows, and chuck voltage need to be transitioned to levels which are optimal for the removal of the native oxide on the surface of the polysilicon film. This transition may involve rapidly increasing the RF bias power applied to the wafer cathode and then decreasing both source and bias powers to a second set of levels. Additionally, although not illustrated, gas flows and gas types would be gradually adjusted.

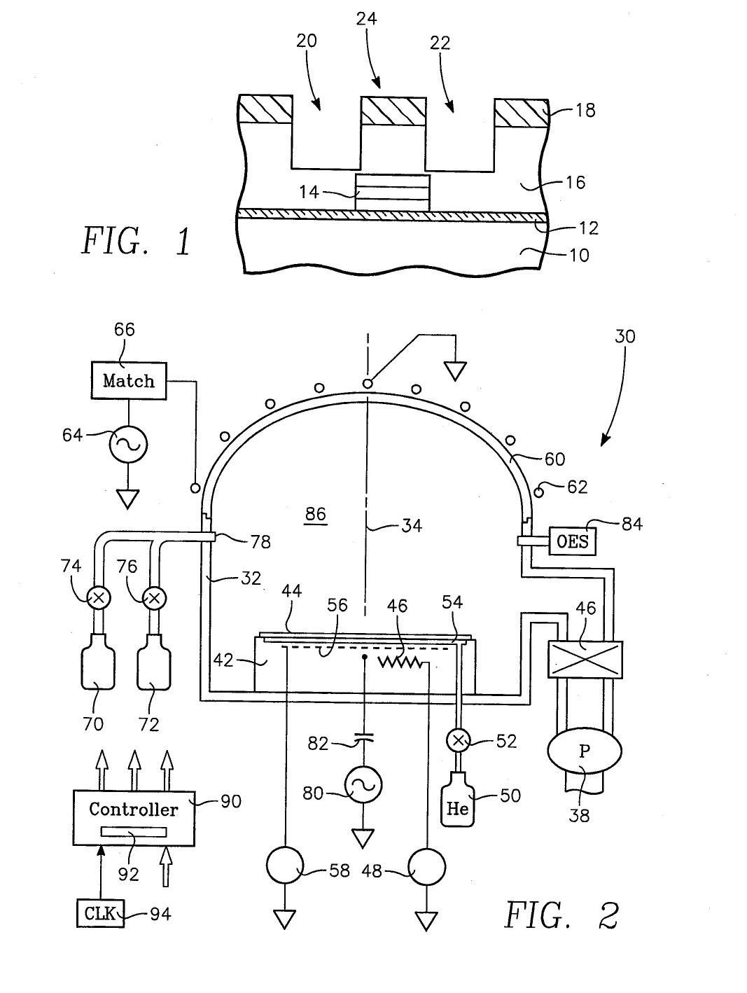

A second example of a processing phase includes the etching of a polysilicon gate, as illustrated in FIG. 1, which requires high selectivity to the underlying gate oxide layer 12. The process needs to be continuously adjusted as the etch front gets closer to the gate oxide. The conventional procedure of dividing the gate etch process into several discrete steps can lead to a gate etch profile with a discontinuous profile, to the production of a foot at the bottom of the profile extending laterally into the polysilicon layer 16, and to excessive recessing of the underlying gate oxide layer 12, which is very thin. The discrete steps are ineffectual at overcoming these profile problems because the highly selective gate etch is very sensitive to gas composition but this composition is also changing during the plasma process due to the participation of etch by-products. Further, etch stop needs to be avoided during the etching process before the gate etch is completed.

The trajectories for three important parameters for one embodiment of the gate etch are illustrated in FIG. 5. Plot 130 shows the trajectory for the chamber pressure in milliTorr; plot 132 shows the trajectory for the flow of oxygen in sccm; and, plot 134 shows the bias power applied to the pedestal cathode in watt. A halogen main etch gas may also be supplied. During the etch process, all three parameters are nearly continuously adjusted. The gas pressure 130 slowly increases from 4 milliTorr to 10 milliTorr. The RF bias power 134 is initially maintained at a level of 250 W for the first portion of the etch but then gradually decreases to 50 W during the second portion to decrease the hard sputter etching. The amount of oxygen added to the process gas mixture starts at 1 sccm and is ramped up to 6 sccm in the middle portion of the etch but then rapidly decreases to 2 sccm in the final seconds of the etching process.

The control process can be further generalized by relying upon chamber sensors to monitor the progress of the plasma process and accordingly readjust the trajectories. As illustrated in the flow diagram of FIG. 6, the sensors 112 can be used not only to control the transition process at 108 to terminate a processing phase, they can also be used in updating the trajectory at 102 to adjust the trajectory in the remainder of the phase. The adjustment may including changing values of the end values or the changing the shape of the trajectory. Examples of independent sensors are VI (voltage current) probes associated with the power supplies 58, 82 for the electrostatic chuck 56 and the pedestal biasing, current meters for the electrostatic chuck, the previously described end point detection of the optical emission spectrometer 84, unillustrated magnetic or electric field probes or ion flux probes, and feedback from the mass flow controllers. Also, the previously mentioned local controllers can act as sensors providing feedback information for the element they control. The trajectory updating may also be based on previous wafer runs including measured previously measured sensor values sensitive to chamber conditions, thereby including details of the history of the chamber. Trajectory constants may be updated on a run-to-run basis from integrated metrology, in-situ metrology, or equipment data in both the feed forward and feed backward mode.

The trajectories can be parameterized in an equation with input coefficients including the start and stop values defining the exact trajectory. In the simplest case, time is the only variable of the equation. The trajectories of FIG. 4 demonstrate that a trajectory can be defined by a set of interconnected linear portions defined by respective linear equations valid for set time periods within the process phase. The trajectories of FIG. 5 demonstrate that a higher-order equation, such as a quadratic equation, may be required to accurately calculate the trajectory at any time point. If necessary, a series of interconnected higher-order equations may be used.

Additionally, the temporally varying outputs of the sensors described above may provide additional variables in the trajectory equation, thereby decoupling the parameter behavior from a fixed sequence. Alternatively, the trajectory may be defined through a table of set points (parameter values), where a set of set points is defined for each cycle period. The table may be determined empirically or otherwise. In contrast, the traditional control process defined a set of set points and a time period during which they would be operative.

The trajectory control defines the temporal evolution of one or more traditional recipe set points as well as the set points of local controllers. Examples of local controllers include self-controlled actuator systems use to control traditional chamber control parameters, such as the throttle valve, match position, heater percentage output, and helium pressure regulator.

The invention thus enables a new method of operating an otherwise conventional plasma processing chamber to provide much finer and closer control of parameters critically defining the etch process and resultant etched structure. The improvements are provided in large part by computer code incorporated into the controller and the recordable medium controlling it. As a result, retrofitting of existing processing equipment is easily accomplished.

1. A plasma processing system, comprising:
a plasma processing chamber for processing a substrate and including a plurality of parameter functions for controlling the processing, at least one power supply operatively associated with a plasma within the chamber, and at least one gas supply supplying a gas for the plasma; and
a control system operatively coupled to the chamber, the control systems controls the plurality of parameter functions according to respective trajectories extending over a time period between respective start values and stop values and being controlled at a plurality of temporal points within the time period separated by a fixed time increment.

2. The system of claim 1, wherein the trajectories are defined by respective equations having at least time as a variable.

3. The system of claim 2, further comprising a clock providing a signal for the time in the equation.

4. The system of claim 2, further comprising a sensor operatively associated with the chamber to monitor the processing and providing a sensor signal for another variable for at least one of the equations.

5. The system of claim 1, wherein the plasma processing chamber is a plasma etching chamber and the processing gas includes an etching gas.

6. A method of controlling a plasma processing chamber, the method comprising:
setting start and stop values for a plurality of control functions extending over a time period for plasma processing a substrate within the chamber;
defining trajectories of the control functions connecting the start and stop values over the time period; and
at each of a plurality of differing time points within the time period, determining values of the control functions according to the trajectories.

7. The method of claim 6, wherein the plurality of time points are separated by a fixed time increment.

8. The method of claim 6, wherein the trajectories are defined by respective equations having time as a variable.

9. The method of claim 8, further comprising sensing at each of the time points a condition associated with the chamber and providing a sensed signal as a second variable in at least one of the equations.

10. The method of claim 6, further comprising sensing at each of the time points a condition associated with the chamber and accordingly adjusting at least one of the trajectories.

11. The method of claim 6, further comprising:
controlling an amount of a gas supplied into the chamber according to a first one of the control functions; and
supplying an amount of power to generate a plasma of the gas according to a second one of the control functions.

12. The method of claim 6, wherein the time increment is fixed.

13. The method of claim 5, further comprising the steps of:
determining if the time period has been reached;
if the time period has been reach,
setting second start and stop values extending over a second time,
defining second trajectories of the control functions connecting the second start and stop values over the second time period, and
at each of a plurality of time points within the second time period, determining values of the control functions according to the second trajectories.

14. The method of claim 6, wherein the plasma processing chamber is a plasma etch chamber and further comprising supplying an etching gas into the plasma etch chamber to etch the substrate.

15. The method of claim 14, wherein the substrate includes a polysilicon layer and the etching gas selectively etches it to an underlying oxide layer.
